(19) United States
(12) Patent Application Publication
(10) Pub. No.: US 2025/0309024 A1
(43) Pub. Date: Oct. 2, 2025

(54) Electronic Device Component with Improved Thermal Characteristics

(71) Applicant: Diamond Foundry Inc., South San Francisco, CA (US)

(72) Inventor: Jean-Claude Harel, San Jose, CA (US)

(21) Appl. No.: 19/233,064

(22) Filed: Jun. 10, 2025

Related U.S. Application Data
(63) Continuation of application No. PCT/US23/23894, filed on May 30, 2023.
(63) Continuation-in-part of application No. 18/679,212, filed on May 30, 2024.
Application No. 18/679,212 is a continuation of application No. PCT/US22/50538, filed on Nov. 21, 2022.
(60) Provisional application No. 63/288,066, filed on Dec. 10, 2021.

(51) Int. Cl. H01L 23/34

(52) U.S. Cl. CPC H01L 23/34

(57) ABSTRACT

An integrated device component having improved thermal characteristics includes a semiconductor device, a layout layer disposed on the semiconductor package; and a wafer located on top of the layout layer. The wafer is composed of a material chosen to be electrically resistive and have a uniform thermal conductivity in a lateral and transverse direction of greater than or equal to 1900 watts per Meter Kelvin with a variation over the surface of the substrate of plus or minus 1 degree Celsius.

### BENEFIT OF PRIORITY

This Application is a continuation of International Application number PCT/US2023/023894 filed May 30, 2023 and published as International Patent Application Publication number WO 2024/023894, the entire contents of which are incorporated herein by reference. This Application is also a continuation-in-part of U.S. patent application Ser. No. 18/679,212 filed May 30, 2024 and published on May 30, 2025 as U.S. Patent Application Publication number US-2025-0174513, the entire contents of which are incorporated herein by reference. U.S. patent application Ser. No. 18/679,212 is a continuation of International Patent Application number PCT/US2022/050538 filed Nov. 21, 2022 and published as International Patent Application Publication number WO 2023/107271, the entire contents of which are incorporated herein by reference. International Patent Application number PCT/US2022/050538 claims the benefit of priority to U.S. Provisional Application 63/288,066 filed on Dec. 10, 2021, the entire contents of which are incorporated herein by reference.

### FIELD OF THE DISCLOSURE

Aspects of the present disclosure relate to substrates for semiconductor devices. Specifically, aspects of the present disclosure related to diamond substrates for semiconductor devices.

### BACKGROUND OF THE DISCLOSURE

### Advancing Energy Efficiency in EV Power Electronics

Power inverters convert the direct current (DC) voltage from a battery to alternating current (AC), e.g., 3-phase AC format compatible with the electric traction motor. In a 3-phase AC format, each phase requires two power switches mounted in a so-called “half bridge” topology. During operation, because the three-phases are shifted at a 120-degree angle, always two switches are closed (ON) simultaneously, the other four being open (OFF).

In order to evaluate the inverter efficiency, conduction losses are calculated from the voltage difference when the switch is closed multiplied by the current flowing into the switch, of course multiplied by 6(3×2=6 switches). The level of power losses generated is substantial, and designers always have tried to reduce it to increase driving range or battery size reduction. Some other considerations such as wire-bonds' stress and capacity, gate-drivers' performances and overall system size and cost are as well part of the equation when designing a power traction inverter. So far, the rule of thumb to reduce power losses has been to use more silicon surface area or use a better heat sink. Both approaches have significant drawbacks. Using more silicon switches reduces power conduction losses since the “ON” state current is shared among a greater number of switches therefore reducing the power to be dissipated. However, the switching losses increase accordingly especially with insulated gate bipolar transistors (IGBTs). The drawback is the exponential surface attachment to be used, the multiplication of weak links in the power path such as wire bonds, the disparity from die to die, the physical distance expansion leading to detrimental parasitic inductances and the difficulty of perfectly synchronizing each die to its companion die, eventually ending with an unnecessary complexity and poor efficiency for the effort deployed. Furthermore, cost considerations make this approach problematic.

Cooling strategy on the other hand has been a topic of experiments and research and development for many years. Rather than only focusing on silicon improvements, designers had a sense that reducing the operating temperature of the dies could be the path to power efficiency, cost reduction and greater reliability. Though that intuition is certainly correct, nowadays available materials to ensure a satisfying result is by far unreachable.

Because the electrical and thermal paths for power silicon are identical and both of substantial magnitude, it is extremely challenging to literally disconnect them to direct the thermal path to a liquid coolant that needs to be electrically isolated for safety reasons and the electrical path that needs to be as short and resilient as possible. That disconnection mechanism (the “dielectric”) is accomplished through techniques and technologies illustrated in FIGS. 1A-1C that have not really evolved significantly over the past four decades, achieving poor results despite being largely adopted.

FIG. 2 depicts a common architecture for a power device. Generally, the device includes a silicon die 201 that is attached by an attachment 202 to a copper layout 203, which is thermally coupled to a coolant 206 via a substrate 204 and dielectric material 205. Electric current flows mainly laterally in the copper layout 203 but mainly vertically from the die 201 through the attachment 202, layout 203, substrate 204 and dielectric 205. Such an architecture is characterized by relatively poor two-dimensional vectorial thermal propagation in the thermal path between the silicon die 201 and the coolant 206. For example, if the coolant 206 is at a temperature of about 80° C., the die 201 is typically at a temperature of 175-200° C. due to thermal impedance in the thermal path. The common architecture of FIG. 2 can be decomposed by the simplified thermal-impedance (Rth) model shown in FIG. 3A and summarized in the table shown FIG. 3B.

FIG. 3 shows that thermal impedance (Rth) between the die 201 and the coolant 206 is spread into three main categories:
1) Dielectric material 205 (Rth4): With a large range of performances and characteristics, dielectric materials must ensure the best thermal conductivity achieving automotive isolation requirements in the order of 4kV for 1 minute, dictating the material thickness therefore Rth.
2) Substrates and mechatronics (Rth2, Rth6, Rth8): Substrates offer mechanical robustness and die mountability as well as exposed surfaces ensuring the thermal continuity to the coolant through the inverter system (mechatronics).
3) Surfaces junction is the point of junction of different elements mounted together and can be categorized in 3 main groups:
a) Soldering or sintering diffusion (Rth1) that offer the best thermal conductivity depending on the material used, interface thickness and thermal conductivity.
b) Deposition coating of ceramics to metal (e.g., Al2O3 flame spray coating) inducing an inter-material interface with its own Rth (Rth3, Rth5) depending of porosity and penetration;
c) Pressure contact (Rth7) where two surfaces are pressed together to create a thermal path (often the electric path too). This type of interface is highly dependent on the pressure applied, coplanarity, roughness and geometries of the surfaces. It is usually of poor performance and degrades with time.

Though non-intuitive, liquid to solid surface contact (Rth8) is part of this category but is more stable and of better quality/performance depending on the strategy adopted. Laminar flow on a planar surface exhibits a reduced efficiency since only a few molecules at the coolant surface contact to the solid surface will carry the calories to be extracted. The rest of the liquid does not participate actively in the cooling. Turbulent flow creates a greater surface contact area and more carriers but requires a special mechanism to be implemented leading to a greater use of material and system volume increases (i.e., thin fins). As seen above, the total junction to coolant Rth is more an agglomeration of material properties, techniques, and surface area than a single dimension issue. There is a substantial margin for progress.

Advancement in power inverters has been slow and incremental due to complex design and manufacturing aggravated by custom subsystems requirements, sophisticated integration of high-power electronics, material science, mechatronics, and thermal management. Power density is certainly the key metric of performance for modern power inverters underscoring technology and efficiency. As a reference, state-of-the-art designs exhibit 33 kW/L (Tesla Model 3 is 12 L, 4.8 kg, 400 kW) and 36 kW/L (Audi e-Tron is 5.5 L, 8 kg, 200 kW).

Power semiconductor devices are essentially driven by two factors: Thermal conductivity—the path to cool them down—and electrical conductivity—the path to carry high currents. Though the electrical path has been worked on for many years with more or less success, the thermal path has always been the main challenge.

Besides the need for high thermal and electrical conductivity, power semiconductor devices need to be isolated from the rest of the environment because they carry high voltages; this is a safety requirement. Voltage isolation barriers (like DBC substrates) usually demonstrate poor thermal conductivity. Common isolation barriers like high thermal conductivity compounds exhibit 2 to 5 W/mK thermal conductivity. State of the art oxides such as Aluminum Oxide (Al₂O₃) show a 24 to 28 W/mK thermal conductivity. More modern Aluminum Nitride (AlN) realistically offers 150 to 180 W/mK thermal conductivity. Therefore, with these materials there is a substantial undesirable thermal difference in between the semiconductor junction temperature (Tj) and the cooling mechanism (usually liquid glycol) at the thickness required to ensure electrical isolation.

Power semiconductor devices such as Silicon Insulated Gate Bipolar Transistors (Si IGBTs) and Silicon Carbide metal oxide semiconductor field effect transistors (SiC MOSFETs) have the same electrical and thermal path through their bottom side unlike other power dissipating devices such as MCU, logic, memory and DSP chips. Today's most common solution to ensure electrical insulation, and high current carrying capability for Si IGBT and SiC MOSFETs are Direct Bonded Copper (DBC) substrates. Unfortunately, they do not provide high heat carrying capacity.

It is within this context that aspects of the present disclosure arise.

### BRIEF DESCRIPTION OF THE DRAWINGS

The teachings of the present disclosure can be readily understood by considering the following detailed description in conjunction with the accompanying drawings, in which:

FIGS. 1A-1C depict thermal profiles and a side schematics view of different wafer types showing the General Impact of Adding Diamond to Power Electronics in prior art implementations.

FIG. 2 depicts a cross section view of a prior art electrical/thermal path in a power device.

FIG. 3A is a thermal impedance Rth model representation of the prior art electrical/thermal path in a power device.

FIG. 3B is a table containing relevant values for calculation of the thermal impedance for an example prior art electrical/thermal path in the power device.

FIG. 4A is a line graph showing the normalized on-resistance (RdsON) versus temperature of a typical Silicon Carbide (SiC) power device.

FIG. 4B is a line graph depicting the saturation voltage across the collector and emitter (V_{CE(sat)}) vs temperature for a typical IGBT device.

FIG. 5 is a table summarizing power conduction losses for a 3-phase 250 kW inverter system translated into a standard EV sedan range according to current power device standards

FIG. 6 is cross section view of the improved Thermal-Electrical path power devices according to aspects of the present disclosure.

FIG. 7 is a thermal impedance (Rth) model representation of the improved electrical/thermal path power device according to aspects of the present disclosure.

FIG. 8 is a table containing relevant values for calculation of the thermal impedance for an example improved electrical/thermal path power device.

FIG. 9 is a view of a metal base substrate used in the fabrication of single crystal diamond substrates for silicon transistors according to aspects of the present disclosure

FIG. 10 is a view showing the alignment of the metal base substrate on a metal base substrate assembly during fabrication of single crystal diamond substrates for silicon transistors according to aspects of the present disclosure.

FIG. 11 is a view depicting placement of a first stencil and placement sintering paste the metal base substrate during fabrication of single crystal diamond substrates for silicon transistors according to aspects of the present disclosure.

FIG. 12 is a view showing a single crystal diamond wafer being added on top of the sintering paste during fabrication of single crystal diamond substrates for silicon transistors according to aspects of the present disclosure.

FIG. 13 is a view depicting placement of a second stencil and a second layer of sintering paste and applied over top the single crystal diamond wafer during fabrication of single crystal diamond substrates for silicon transistors according to aspects of the present disclosure.

FIG. 14 is view showing placement of a thin metal layer on top of the second sintering paste layer a single crystal diamond wafer during fabrication of single crystal diamond substrates for silicon transistors according to aspects of the present disclosure.

FIG. 15 is a view depicting sintering the assembly stack using a sintering press during fabrication of single crystal diamond substrates for silicon transistors according to aspects of the present disclosure

FIG. 16 is a view showing removal of the sintering press and sintering dye leaving a completed SCD component during fabrication of single crystal diamond substrates for silicon transistors according to aspects of the present disclosure.

FIG. 17 is a view depicting removal of the SCD component from the dum bars during fabrication of single crystal diamond substrates for silicon transistors according to aspects of the present disclosure.

FIG. 18 is a view showing etching of a SCD component during fabrication of a device package according to aspects of the present disclosure.

FIG. 19 is a view depicting removal of the SCD component from the dum bars and application of sintering paste during fabrication of a device package according to aspects of the present disclosure.

FIG. 20 is a view showing sintering of metal bus bars to the SCD component during fabrication of a device package according to aspects of the present disclosure.

FIG. 21 is a view showing the silicon devices sintered to the SCD component during fabrication of a device package according to aspects of the present disclosure.

FIG. 22 is a view depicting bond wires conductive coupling the silicon devices to the metal bus bars during fabrication of a device package according to aspects of the present disclosure.

FIG. 23 is a view showing potting die formed to fit the SCD component, bus bars and silicon device assembly during fabrication of a device package according to aspects of the present disclosure.

FIG. 24 is a view depicting the SCD component, bus bars and silicon device assembly placed in the potting die and aligned via alignment pets in the potting die during fabrication of a device package according to aspects of the present disclosure.

FIG. 25 is a view showing the finished potted device package according to aspects of the present disclosure.

FIG. 26 is a view depicting the doping of the single crystal diamond wafer to create a layout layer of doped diamond and without the metal substrate and dum bars according to aspects of the present disclosure.

FIG. 27A is a view depicting an optional step in the creation of the layout layer wherein the doped diamond layer is coated with a metal layer.

FIG. 27B is a view showing etching the layout layer that includes doped diamond according to aspects of the present disclosure.

FIG. 28 is a view depicting the application of sintering paste to the layout layer for bus bars according to aspects of the present disclosure.

FIG. 29 is a view showing sintering of metal bus bars to the SCD component having a layout layer including doped diamond during fabrication of a device package according to aspects of the present disclosure.

FIG. 30 is a view depicting silicon devices sintered to the SCD component having a layout layer including doped diamond during fabrication of the integrated device package according to aspects of the present disclosure.

FIG. 31 is a view showing bond wires conductive coupling the silicon devices to the metal bus bars during fabrication of a device package according to aspects of the present disclosure.

FIG. 32 is a view depicting the SCD device package undergoing a high voltage thermographic test with a thermographic testing device according to aspects of the present disclosure.

FIG. 33A is a thermographic image of an inverter device with an Aluminum Nitride insulator under a high load.

FIG. 33A is a thermographic image of an inverter device with a SCD insulator under a high load.

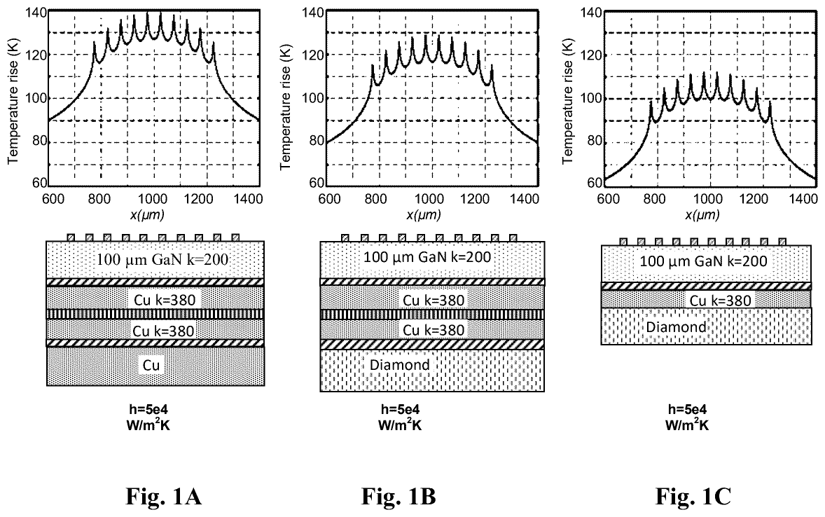

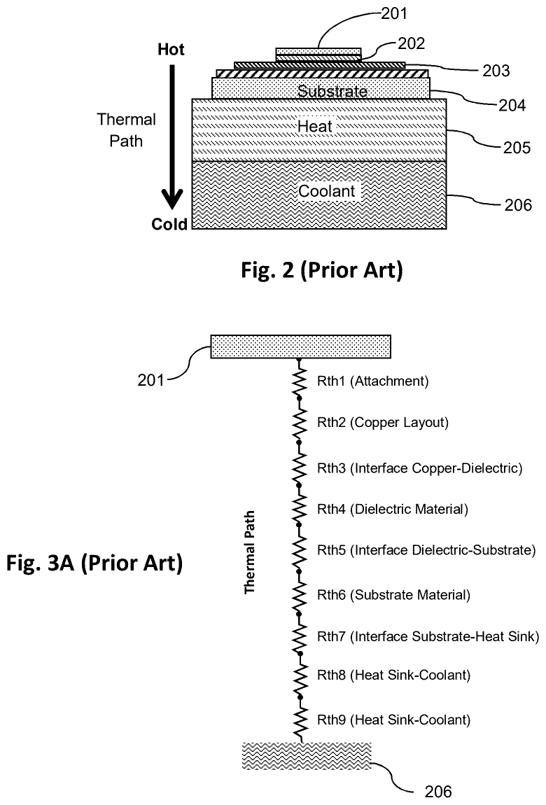

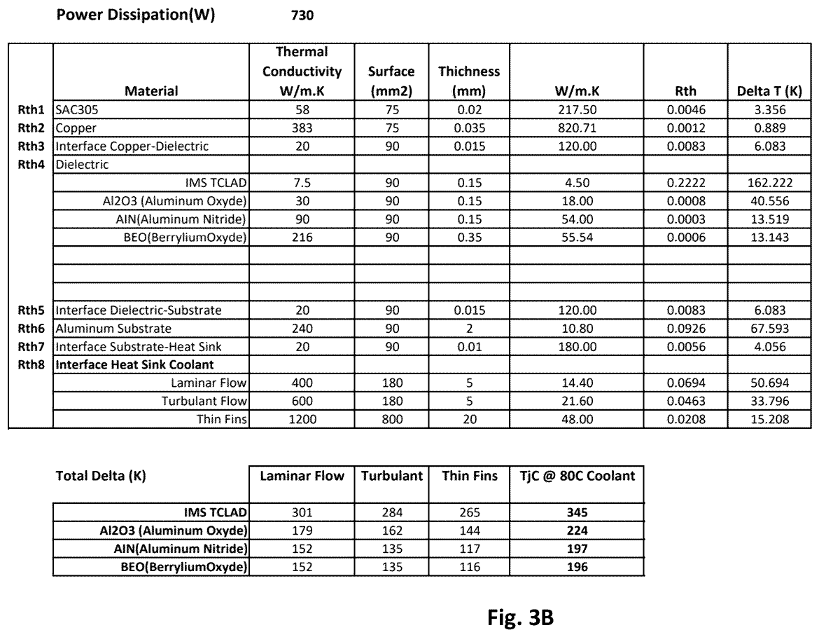

### DESCRIPTION OF THE SPECIFIC EMBODIMENTS

Although the following detailed description contains many specific details for the purposes of illustration, anyone of ordinary skill in the art will appreciate that many variations and alterations to the following details are within the scope of the invention. Accordingly, the exemplary embodiments of the invention described below are set forth without any loss of generality to, and without imposing limitations upon, the claimed invention.

### Introduction

### Overview

Electronic vehicle (EV) power electronics has increasingly become heat dissipation limited, and the potential range of electronics architectures has been limited by available materials. The thermal stress induced into power semiconductor switches has been difficult for semiconductor and inverter companies. Engineers across the entire industry have been stuck using materials in their electronics design that do not truly meet the characteristics required for advancing EV power electronics, such in particular including a material that combines extreme thermal conductivity with extreme voltage insulation.

Single-crystal diamond (SCD) is a most extreme material-in multiple dimensions and by a decisive factor each-in particular through its combination of extreme thermal conductivity and extreme electrical insulation. SCD exhibits remarkable dielectric properties including a low dielectric constant of 5.7, a loss tangent below 0.0001 at 35 GHz and a high dielectric strength of 10 MV/cm. This means 20 μm (2×10⁻⁵ m) of SCD can insulate 20 kV while at the same time delivering thermal conductivity as high as 3,000 W/mK.

Diamond Foundry, Inc. of South San Francisco, California has achieved production of single-crystal diamond in wafer dimensions covering the die sizes required by commercially relevant computer and power-electronics chips. Such sizes include, but are not limited to 1 cm×1 cm, 2 cm×2 cm, 3 cm×3 cm, 4 cm×4 cm, 5 cm×5 cm as well as sizes intermediate the aforementioned sizes. In particular, squares made of SCD are available in sizes that range from 1×1 mm to 50×50mm by increments of 1 mm. In addition, circular (disk) SCDs with diameters ranging from 1 mm to 100 mm became available in 2023, with sizes up to 200 mm projected to become available in 2024-25.

### The Power Traction Inverter Dilemma

An EV's Power Traction Inverter (PTI) is a critical element of electric mobility. Because of their level of complexity, electrical and thermal stress and cost, PTIs have always been one of the weakest links of the electric mobility implementation, with a remarkable level of failure on the early development of this emerging market, and certainly a technological barrier of entry for OEM adoption. Driving conditions and style often induce substantial electrical and thermal stress to the active components of the inverter and their surrounding elements and if not properly addressed leads to drastic life reduction and eventually failures of the system.

Power semiconductor device performance is essentially driven by two factors: Thermal conductivity—the path to cool them down—and electrical conductivity—the path to carry high currents. Though the electrical path has been worked on for many years with more or less success, the thermal path has always been the main challenge.

Besides the need for high thermal and electrical conductivity, power semiconductor devices need to be electrically isolated from the rest of the environment because they carry high voltages; this is a safety requirement. Unfortunately, voltage isolation barriers (like DBC substrates) usually demonstrate poor thermal conductivity. Common isolation barriers like high thermal conductivity compounds exhibit 2 to 5 W/mK, state of the art oxides such as Aluminum Oxide (Al₂O₃) show a 24 to 28 W/mK, more modern Aluminum Nitride (AlN) realistically offer 150 to 180 W/mK, therefore keeping a substantial undesirable thermal difference in between the semiconductor junction temperature (Tj) and the cooling mechanism (usually liquid glycol) at the thickness required to ensure electrical isolation.

Power semiconductor devices such as Silicon Insulated Gate Bipolar Transistors (Si IGBTs) and Silicon Carbide metal oxide semiconductor field effect transistors (SiC MOSFETs) have the same electrical and thermal path through their bottom side unlike other power dissipating devices such as MCU, logic, memory and DSP chips. Today's most common solution to ensure electrical insulation, and high current carrying capability for Si IGBT and SiC MOSFETs are Direct Bonded Copper (DBC) substrates. Unfortunately, they do not provide high heat carrying capacity.

### Diamond Based Power Electronics

Because of its remarkable properties, diamond and diamond based solutions have always been on the far reaching scope of power semiconductors developers. Some would call it the “Holy Grail” for semiconductors applications in nature that it exhibits ultra-high thermal conductivity and ultra-high band gap. Unlike graphene (another allotrope of carbon) which is electrically conductive, diamond is a premium isolator. Diamond Foundry now offers a practical and cost affordable solution to a very old issue: How to implement a cool down path efficiently to a power semiconductor and insure dielectric isolation at the same time.

The advantages of diamond have long been well-known, indeed this not being any surprise or novelty. What is new and disruptive is that Diamond Foundry has now managed to: a) produce high-quality single-crystal diamond wafers for all chip die sizes; b) drive down cost to the levels required by automotive power electronics; and c. novel power electronics architectures that fully utilize the capabilities of novel diamond wafers.

Prior work has shown that diamonds reduce peak temperature by as much as 20% for various semiconductors, such reduction improving power efficiency by 10% during such periods.

SCD wafers can be used close to the switching semiconductor device junction in multiple ways: replace ceramics (e.g., Aluminum Oxide (Al₂O₃), Aluminum Nitride (AlN), Silicon Nitride (Si₃N₄)) in direct-bonded-copper (DBC) substrates; replace heat spreaders in novel discrete packages; allow for thinning the semiconductor wafer. SCD wafers allow inverter size, weight, and cost reductions based on any and all semiconductor technologies, not requiring a “bet” on a novel form of a semiconductor gaining commercial traction.

### The Importance of Sustaining a Lower Junction Temperature

The thermal stress induced into power semiconductor switches yields failure as well as energy efficiency loss. As a general rule of thumb, every 10° C. increase in temperature reduces the semiconductor life expectancy by half, setting for example the trend to higher-temperature resilient silicon designs to 200 C from 175 C for Silicon Carbide power switches. Unlike IGBTs who have an almost constant V_{ce(Sat)} versus temperature coefficient, MOSFET's (including SiC) RdsON is a Positive Temperature Depending Parameter (TDP) which means that RdsON increases with temperature.

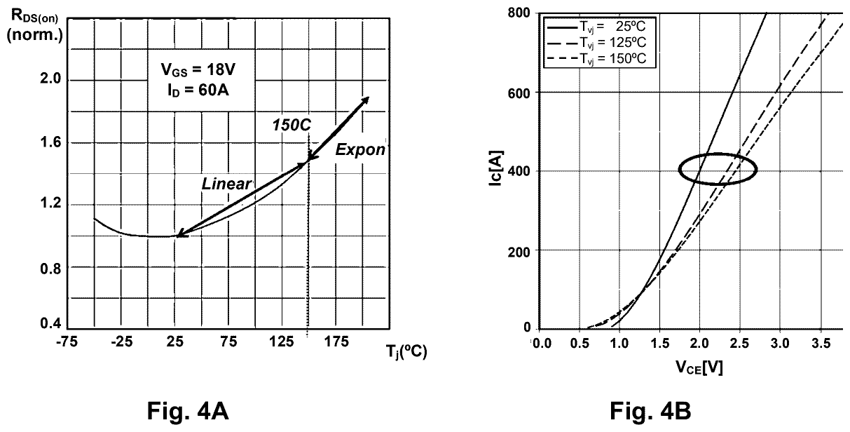

FIG. 4A shows a normalized RdsON for a common SiC device. As the typical RdsON is specified at 25 C to be 1 (e.g., 7 mOhm) it increases 45% (10.39 mOhm) at 150 C, 64% (11.64 mOhm) at 175 C and 90% (12.87 mOhm) at 200 C. The growth of RdsON versus Tj is split into the linear (25 to 150 C) and the exponential region (150 to 200 C) meaning that for the same amount of current (400 A), the power conduction losses will be 1120 W at 25 C, 1359 W at 100 C, 1662 W at 150 C, 1863 W at 175 C and 2060 W at 200 C.

FIG. 4B shows the V_{ce(sat)} for a typical modern IGBT. Conduction losses at 400 A establishes at 800 W at 25 C, 920 W at 125 C and 1000 W at 150 C (no further data available). At the EV's inverter frequency operation (e.g., 15 kHz), conduction losses represent about 60% of the cumulated conduction-switching losses of the device. This is mainly due to the so called “tail effect” of IGBTs and it is directly related to the surface area of the silicon chip, the greater the surface, the bigger the switching losses. Total cumulated conduction and switching losses for IGBTs establishes then to 1375 W at 25 C, 1580 W at 125 C and 1720 W at 150 C. It is remarkable that despite a very slim efficiency advantage to SiC versus IGBTs, the trend of adoption towards SiC appears irreversible with even the predominant cost of SiC versus IGBTs (about 5×) underscoring that implementation cost is undermined in favor of performance and EV's range gain.

Since EV's onboard coolant temperature is typically set to be 80° C. as a standard, the challenge here is to keep the Tj as close as possible to coolant to eliminate the unnecessary conduction losses induced by the Tj in the exponential region and part of the linear region too for SiC and allow for a die surface area reduction for IGBTs. Bipolar structures such as IGBTs are quite resilient in respect of forward current as long as temperature dependent latch-up conditions are not triggered. It is generally admitted that current density of up to 1000A/cm² set the limit and IGBTs manufacturer stay usually within 80% to 90% of this limit over the temperature range. Mastering the junction temperature for IGBTs under the latch-up condition enables a substantial die size active area reduction proportionately impacting the switching losses that IGBTs have been suffering since inception. Properly applied thermal management solutions such as Diamond Foundry solutions could see the equalization of modern SiC and antique IGBTs technologies for E-Mobility frequency switching range (10-20 kHz) at one fifth of the cost.

### Specific Impact on EV Driving Range

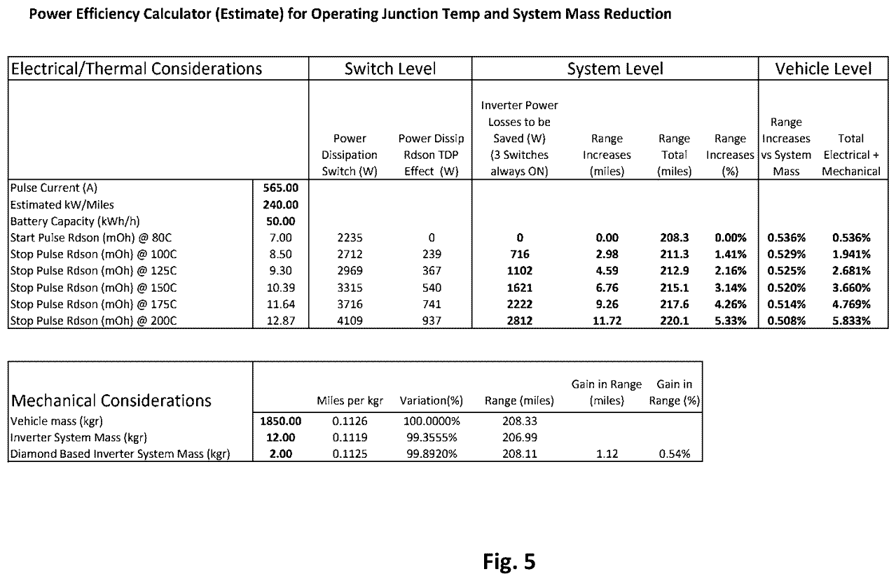

FIG. 5 summarizes the power conduction losses for a 3-phase 250 KW inverter system translated into a standard EV sedan range according to nowadays standards. The 400 A per phase current (565 A peak) induced losses are studied across 80 C (coolant) to 200 C Tj.

The “Inverter Power Losses to be Saved” column shows the energy to be saved from the battery at various Tj, and the range is calculated accordingly from the battery capacity. Assuming the power switches Tj can be kept near by the coolant temperature (80 C) the total power losses saving could reach up to 2812 W per battery charge or 11.72 miles or 5.33% range increase.

This study is conservative in that it does not take into consideration the regenerative power saving which is estimated to be 15-20% of these figures. This includes power losses temperature dependency in Fast Recovery Diodes (FRD) associated to IGBTs, thermal dependency losses of the SiC MOSFET intrinsic diodes (which exhibit poor performances vs temperature) and the reduction of associated circuitry such as gate driver and collateral components. Size reduction in such proportion opens the possibility of a directly integrated inverter-motor eradicating power losses in cables length and terminals, accounting for another few fractions of percent of the battery capacity.

### Single-Form Factor Architecture for EV Power Electronics

Combining the extraordinary thermal-conductivity, voltage-insulation, and wafer-finish properties of single-crystal diamond wafers, available from Diamond Foundry, novel device and system designs as well as more efficient assembly processes are enabled that the industry has not yet had the opportunity to pursue for GaN, SiC and IGBT silicon chips.

In particular, large scale SCD wafers enable single-form-factor power inverters to exceed 1000 k W/L (e.g., 400 kW for a 0.4 L system). This comes with a greater system efficiency, losses and system cost reduction translating into energy saving and electric mobility range extension.

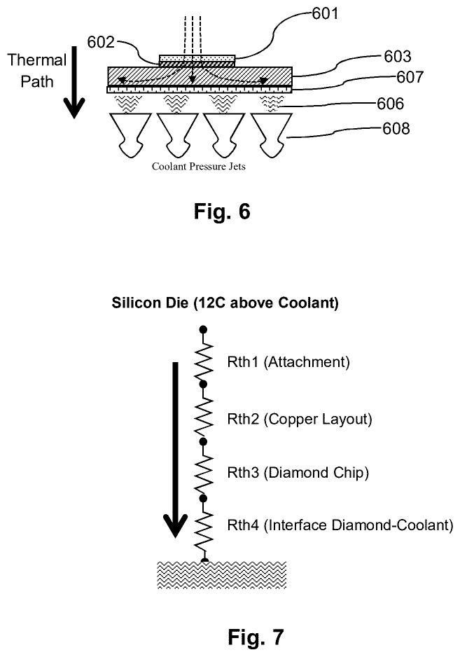

A novel thermal management configuration according to aspects of the present disclosure is shown in FIG. 6. This configuration delivers a drastic reduction of the thermal impedance elements from nine to four elements. In this configuration, a semiconductor die 601 is attached to a copper substrate 603 by a silver attachment 602. The copper substrate 602 is diffusion bonded to a SCD wafer 607. Diffusion processes used for attachment in between the simplified number of elements constituting the thermal path are now reduced to nanometer scale insuring a free thermal propagation from the semiconductor die 1 through the diamond chip 607 to the coolant 606. The use of the SCD wafer 607 allows for a more three-dimensional thermal propagation, as indicated by the dashed arrows.

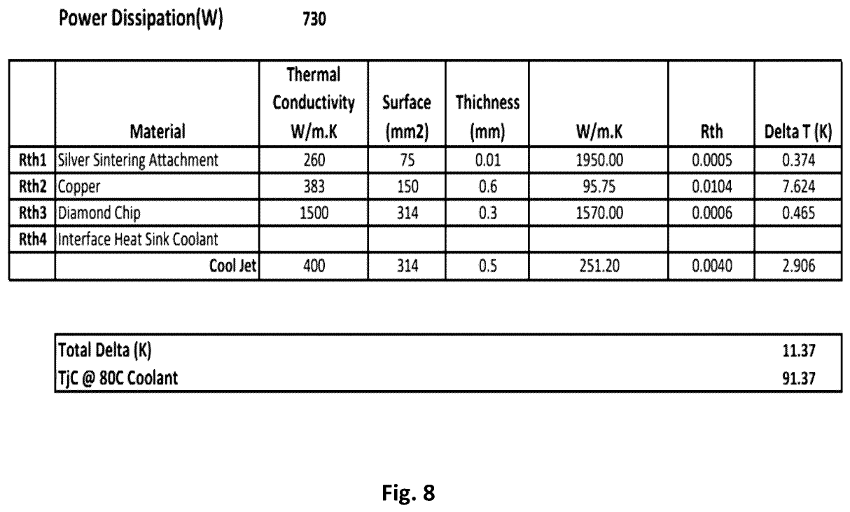

One or more pressurized coolant jets 608 deliver coolant 606 to the exposed surface of the diamond wafer 607, offering a perpendicular-impact flow yielding greater performance than laminar, turbulent, or turbulent “thin fins” solution. The corresponding thermal impedance model depicted in FIG. 7 in the table depicted and FIG. 8 summarize these advantages.

Because the dramatic reduction of total Rth (0.0155 compared to a state of the art value of ˜0.11) the silicon die Tj is now intimately related to the coolant temperature in a lockdown position creating a Tj “clamp” at around 12° C. above the coolant enabling significant saving in conduction losses compared to those described with respect to FIG. 5, optimization of mechanical geometries for the inverter design and the reduction of needed active silicon die surface.

The advanced material and thermal management technology of a configuration like that of FIG. 6 offers a drastic reduction in thermal impedance and inverter size reduction paving the way to substantial EV range extension, cost reduction and extreme reliability. Furthermore, this technology is scalable and adaptable to similar markets where high power efficiency and reliability is mission critical (e.g., power generation, charging station, grid balancing etc. . . ).

### Fabrication of a Single Crystal Diamond Substrate for Silicon Transistors

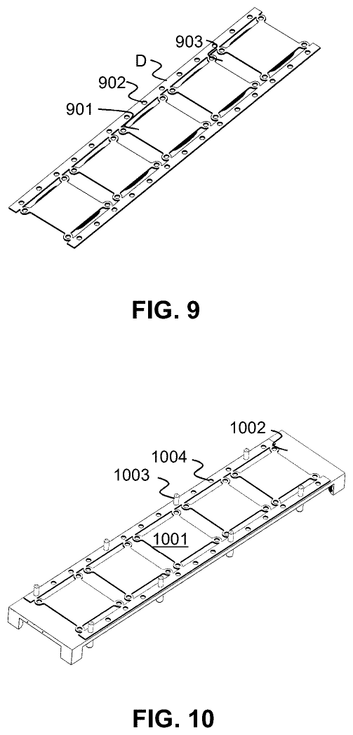

A single crystal diamond substrate for silicon devices may improve thermal conduction. Formation of the single crystal diamond substrate starts with a metal substrate 901 such as the one shown in FIG. 9. The metal substrate 901 may be any suitable metal or metal alloy such as copper, aluminum, silver, gold, nickel or iron. As shown the metal substrate may be included in a fabrication assembly that has alignment holes 902 along dum bars D that may be used to fabricate multiple copper substrates 901 at one time. A cutout 903 separates each metal substrate 901 to case separation. By way of example, the metal substrate may be made of copper 0.590 mm to 1 mm thick and more preferably 0.6 mm thick

As seen in FIG. 10 the metal substrate assembly 1001 may be fitted to an assembly die 1002. The assembly die 1002 may include alignment pegs 1003. Each alignment peg 1003 may be configured to fit into an alignment hole 1004 of the metal substrate assembly 1001.

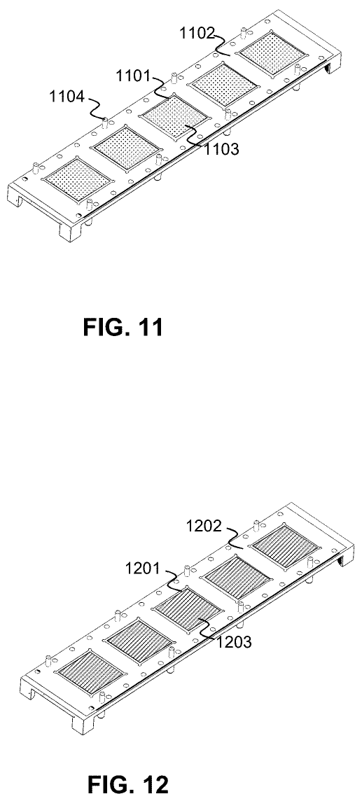

FIG. 11 shows that a first stencil 1102 may be added over top the metal substrate 1101 to aid in application of a first layer of sintering paste 1103. The sintering paste 1103 generally includes metal particles in a binder. By way of example, and not by way of limitation, the sintering paste 1103 may be a silver sintering paste. The alignment pegs 1104 aid in aligning the stencil with the metal substrate and using the alignment holes also present in the stencil 1102. The first stencil 1102 ensures that the first layer of sintering paste 303 is properly located on the substrate 1101. The first layer of sintering paste 1103 may be between 70-90 Micrometers thick before sintering.

In FIG. 12 a single crystal diamond wafer (SCD) 1203 is added on top of the first layer of sintering paste 1103. The first stencil 1202 ensures that the SCD 1203 is properly aligned on top of the sintering paste and the metal substrate 1201. The SCD may be between 50 and 1000 micrometers (5×10⁵ m to 1×10⁻³ m) thick and is preferably 300 micrometers (3×10⁻⁴ m) in thickness. In one implementation, the SCD wafer may be 18 millimeters long by 18 millimeters (1.8×10⁻² m by 1.8×10⁻² m) wide.

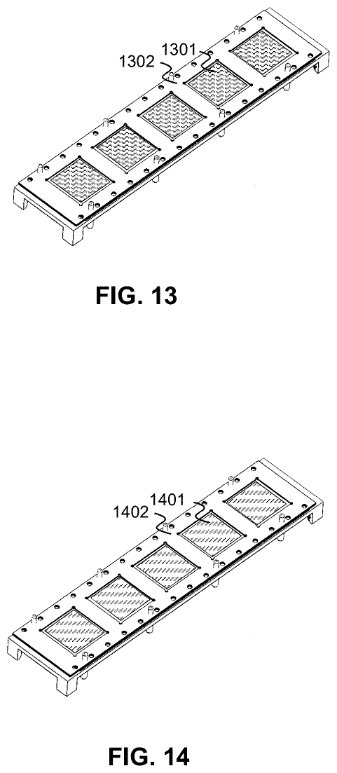

Next, as depicted in FIG. 13, a second layer of sintering paste 1301 is applied over top the SCD layer using the first stencil to align application. Next a second stencil 1302 is placed overtop the first stencil and aligned using the alignment pegs. The second layer of sintering paste 1301 may be between 70 and 90 Micrometers thick.

A thin metallic layout layer 1401 is applied on top of the second layer of sintering paste creating an SCD component assembly stack as shown in FIG. 14. The thin metallic layout layer may be for example and without limitation composed of a thin layer of copper, gold, silver or aluminum. The second template 1402 aligns the thin metallic layout layer 1401 to the proper orientation over the second layer of sintering paste. The thin metallic layout layer may be 30-300 micrometers (3×10⁻⁵−3×10⁻⁴ m) thick with +/−0.1% variation and is nominally 100 micrometers (1×10⁴ m) thick with +/−0.1% variation.

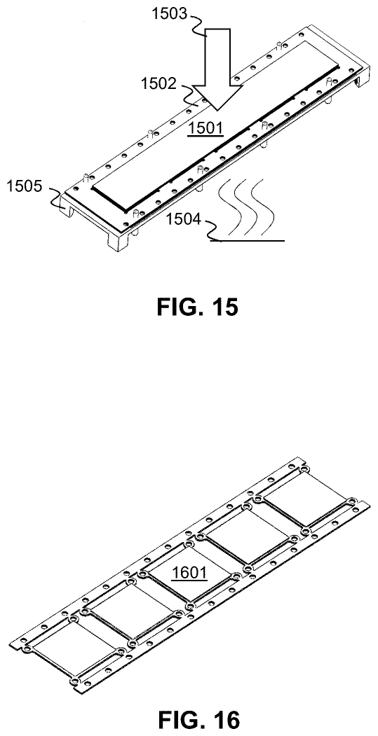

As shown in FIG. 15, a sinter press insert 1501 is placed over the thin metallic layout layer and the second stencil 1502. The sinter press insert 1501 includes protrusions configured to fit into the holes in the second stencil 1502. The protrusions are configured to lie flat against the thin metallic layout layer in the holes of the second stencil 1502. The sinter press insert 1501 also includes cut-out regions to accommodate second stencil 1502 when the force is applied to the sinter press insert and the protrusions press in to the holes of the second stencil 1502.

Next, the assembly stack is sintered. Pressure 1503 is applied to the sinter press insert and the assembly die 1505. While pressure is being applied 1503 the whole assembly is heated 1504 at pressure, temperature and time sufficient to bond the sintering paste to the thin metallic layout layer and the SCD layer and the metal substrate to the SCD layer. In one example implementation, pressure applied between the sinter press insert 1501 to the assembly die 1501 may be around 16 mega Pascals while heated sinter-press platers at 230 degrees Celsius heat the assembly for 6 minutes. Following the application pressure and heat, the sintering paste should be bonded to the SCD layer and the metal substrate layer and the thin metallic layout layer. The final thickness of each of the sintering paste layers may be around 6-10 micrometers.

Finally, as depicted in FIG. 16, the sinter press insert, stencils and assembly die are removed leaving the completed SCD substrate component 1601. Multiple SCD substrate components may be fabricated at one time using dum bars with holes for alignment.

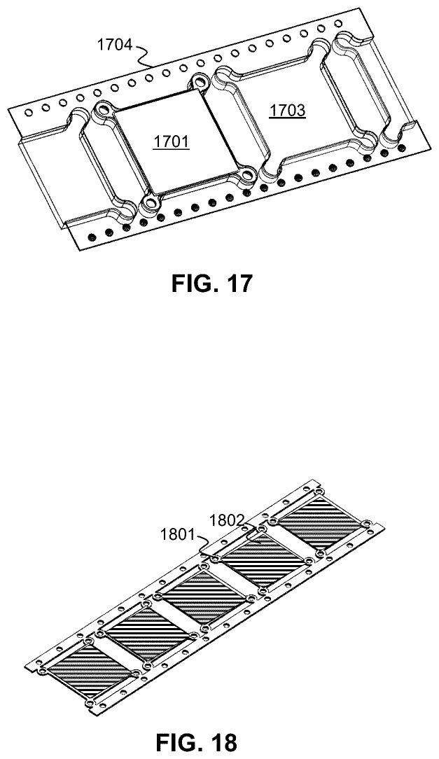

FIG. 17 shows that after sintering and removal of the assembly die, each SCD substrate component may be removed from the dum bars. Removal of the SCD substrate component from the dum bars may be accomplished by any removal means such as cutting or stamping. As shown, some implementations of the SCD substrate component may be fabricated without dum bars and instead the assembly die 1704 includes cutout 1703 for alignment of the copper substrate layer to the assembly die 1704.

### SCD Substrate Component Integrated Device Package

The SCD substrate components may be further integrated into a silicon device package to provide improved cooling for the silicon device. As shown in FIG. 18 the SCD substrate components 1801 may be masked 1802 on the thin metallic layout layer with an etching mask patterned for coupling the SCD substrate component to a semi-conductor device. The etching mask may be any etch masking material known in the art such as a photolithographic mask, mechanically applied mask or the like. The SCD substrate components 1801 having the patterned masks 1802 may then be etched. The etchant may be selective for the thin metallic layout layer on the surface of the SCD substrate device for example and without limitation ferric chloride, nitric acid, hydrochloric acid or aluminum hydroxide.

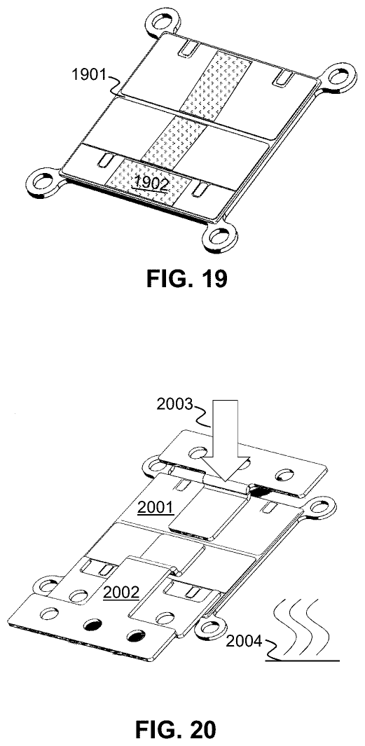

FIG. 19 depicts that the etched SCD component device 1901 may be removed from the dum bars and prepared for integration into a device package. Sintering paste 1902 may be spread in areas on the etched surface of the component device.

Metal bus bars 2002 are placed over the sintering paste on the etched surface of the SCD component device 2001 as shown in FIG. 20. Sufficient pressure 2003 and heat 2004 are applied to the bus bar and SCD component assembly for time sufficient to sinter the bus bars to the SCD component device using the sintering paste. For example, and without limitation to sinter the device the bus bars and the SCD component may have around 16 mega pascals of pressure applied to them through a heated vice or heated press at 230 degrees Celsius for 6 minutes. Once complete the metal bus bars 2002 may be bonded to the etched surface of the SCD component device 2001.

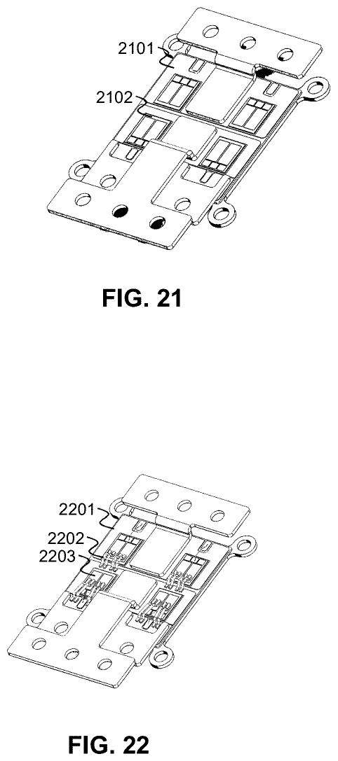

Next, as shown in FIG. 21, one or more silicon devices 2102 such as, for example and without limitation, MOSFETs, Integrated gate bipolar transistors, resistors, diodes, or other types of transistors may be sintered to the etched surface of the SCD component 2101. The silicon devices 2102 may be placed over a sintering paste, such as silver sintering paste, applied to the etched surface of the SCD component 2101. As shown, multiple silicon devices 2102 may be sintered to the surface of the SCD component at a time, pressure and heat sufficient to bond the sintering paste to the silicon devices and the etched surface of the SCD component. For example and without limitation, to sinter the silicon devices to the SCD component around 16 mega pascals of pressure may be applied to the silicon device and SCD component through a vice or press while heating in an oven at 230 degrees Celsius for 6 minutes.

Bond wires 2202 may then be formed, attaching the silicon devices 2203 to a portion of the SCD component 2201 as depicted in FIG. 22. The bond wires 2202 may be formed by any known method such as, for example and without limitation ball bonding, wedge bonding or compliant bonding.

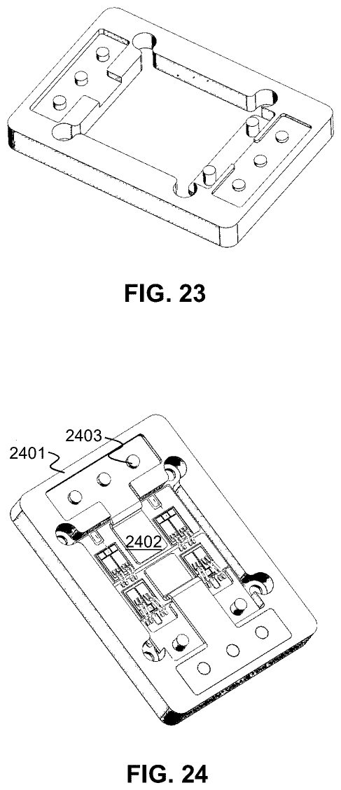

As shown in FIG. 23 a potting die may be created to fit the SCD substrate component integrated assembly. The potting die may include several alignment pins to locate the SCD substrate component integrated assembly properly into the potting dye. The alignment pins may fit into screw holes or other alignment holes in the SCD component or the bus bars.

The SCD substrate component integrated assembly 2402 is then placed into the potting die 2401 using the alignment pins 2403 to ensure proper placement as depicted in FIG. 24. Potting compound solution is poured on top of the SCD substrate component integrated assembly and allowed to cure. The compound solution may be for example and without limitation epoxy potting compound, silicone potting compound, urethane potting compound, polyacrylate potting compound, potting gel or the like.

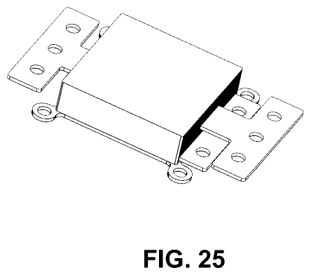

Once the potting compound has cured the SCD substrate component integrated device as shown in FIG. 25 may be removed from the potting die. The SCD substrate component integrated device is complete and may be used in other devices. The SCD substrate allows for excellent cooling of the integrated device as the single crystal diamond provides exceptional thermal conduction and the small cross section created through sintering allows for further improved thermal coupling.

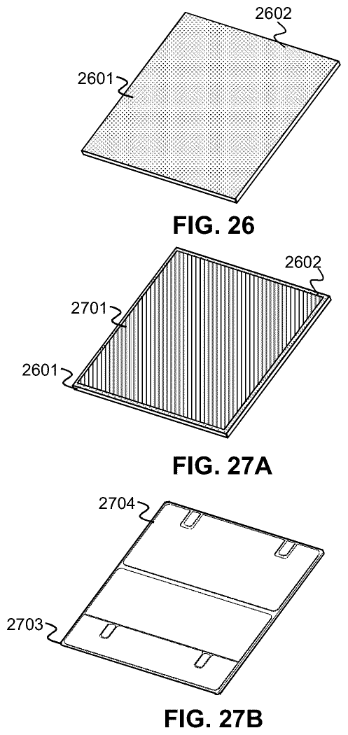

FIGS. 26-31 show a method of making an alternative implementation of the SCD integrated assembly without a metal substrate backing the single crystal diamond wafer. FIG. 26 shows the initial single crystal diamond wafer 2601 and creation of an electrically conductive layout layer 2602 in a portion of the single crystal diamond wafer 2601. The single crystal diamond wafer may be dimensioned to fit one or more semiconductor devices. For example, and without limitation, the SCD may have a transverse dimension (i.e., length or width) greater than 1 mm or greater than 4 mm or greater than 10 mm or greater than 100 mm. Single crystal diamond wafers of such sizes are available from Diamond Foundry Incorporated of South San Francisco. In some implementations the SCD may be circular, in which case the transverse dimension may be a radius of the circular SCD. The lateral axis dimension (e.g., height from major surface to major surface) may be between 10 micrometers and 1000 micrometers, typically 5 mm or 5000 μm.

Alternatively, a diamond layout layer may be formed in an atmosphere containing hydrogen or etched using chemical vapor deposition (CVD), thermal hydrogenation, or Plasma Chemical Vapor Deposition (PCVD) in a hydrogen atmosphere to create hydrogen terminated SCD which forms the layout layer. The hydrogen terminated diamond layout layer may have the single crystal structure of the SCD wafer and as such may be a portion of the SCD wafer. The hydrogen terminated diamond layout layer may be made further electrically conductive through atmospheric transfer doping of the hydrogen terminated diamond. The surface of the hydrogen terminated diamond may be exposed to one or more non-metallic chemicals selected from a list consisting of N₂O, O₃, NO and SO₂. The surface of the diamond layout layer may be exposed to the non-metallic chemicals at concentrations between 1 parts per million (PPM) and 5 PPM. Alternatively, the surface of the hydrogen terminated diamond layout layer may be coated in a metal selected from a list consisting of titanium, MoO₃, V₂O₃, WO₃, ReO₃, NbO₃, and CrO₃.

The metal may be deposited on the surface of the diamond layout layer by any suitable deposition method for example and without limitation, physical vapor deposition, e.g., sputtering. The thickness of the deposited layer may be from 0.1 to 10 nm thick. In some implementations the surface of the hydrogen terminated diamond layout layer or the surface transfer doped diamond layer may have Al₂O₃ disposed on the surface by any suitable deposition method for example Plasma Enhanced Atomic Layer Deposition, to encapsulate and stabilize the surface of the diamond layout layer.

FIG. 27A depicts an optional implementation of the present disclosure wherein a thin layer of metal 2703 is disposed on the doped surface 2602 of the layout layer on the SCD wafer 2601. The thin layer of metal 2703 may be, for example, 50-200 nanometers of Silver (Ag), Gold (Au) or Platinum (Pt). Other suitable metals include, for example and without limitation, copper and aluminum. The thin layer of metal 2703 may be deposited on the doped surface of the SCD wafer by any suitable metal deposition method for example and without limitation, filament evaporation, electron beam evaporation, flash evaporation, induction evaporation, or sputtering. The thin metal layer 2703 may improve the conductivity of the doped portion 2602 of the SCD wafer. Additionally, the thin metal layer may also be patterned and etched as part of the layout layer.

FIG. 27B shows the etched layout layer 2704 disposed on the surface of the SCD wafer 2703. As discussed above, in some implementations the layout layer 2704 may be a doped portion of the SCD wafer. In other alternative implementations, the layout layer 2704 includes both a doped portion of the SCD wafer or a doped diamond crystal layer and a thin metal layer formed on top of the doped portion of the SCD wafer. In yet other alternative implementations, the layout layer is a metal layer deposited on the surface of the SCD. In further implementations as discussed above a layer of sintering paste may be applied between the metallized SCD wafer and a metal layer, sufficient heat and pressure may be applied to the SCD wafer and metal to sinter the metal layer to the metallized SCD wafer. In some implementations, layout layer may be diffusion bonded to the metallized SCD. By way of example, the SCD may be metallized with a layer of silver and the layout layer may be silver or another metal, such as copper, with a silver coating. The metallization on the SCD may then be bonded to the layout layer by silver to silver diffusion, e.g., at a pressure of about 26 Megapascals (MPa) and a temperature of about 220 C. To facilitate such diffusion bonding it is desirable that the surfaces being bonded have relatively low surface roughness (Ra), e.g., <200nm for both surfaces.

The layout layer may be between 30 micrometers to a few millimeters thick in a lateral axis. In implementations with a metal layout layer, the layout layer may be any suitable metal for example and without limitation, copper, gold, silver or aluminum. As discussed above the layout layer 2704 may be patterned with any suitable patterning method for example and without limitation a photoresist material may be applied to the surface of the layout layer and a pattern may be applied using a stencil with light at a wavelength chosen to cross link bonds within the photoresist material. The material not crosslinked by the light may be washed exposing the surface of the layout layer in holes where the photo resist was washed away. The layout layer 2704 may then be etched through the holes in the photoresist material with an etchant suitable for the material of the layout layer.

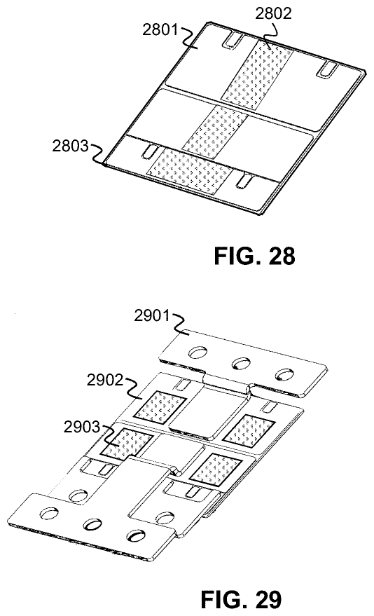

FIG. 28 depicts the application of sintering paste to the layout layer in the formation of the SCD integrated component according to aspects of the present disclosure. As shown a sintering paste 2802 is applied to etched layout layer 2801. The sintering paste 2802 is placed in the location where the bus bars will be located. The sintering paste may be any suitable sintering paste to sinter the bus bars to the layout layer for example and without limitation silver sintering paste or copper sintering paste. The bus bars may them be applied as shown in FIG. 29. The bus bars 2901 are applied over top the sintering paste 2802. Sufficient heat and pressure may then be applied to the bus bars and the SCD wafer with layout layer 2902 assembly to sinter the bus bars to the layout layer. The bus bars may be made from any suitable conductive material, for example and without limitation, copper, steel, aluminum, nickel, tungsten, iron, brass, bronze, or any alloy thereof. Sintering paste 2903 is then placed on the etched layout layer in the location where the silicon device package will be attached. The sintering paste may be any suitable sintering paste for example and without limitation, silver sintering paste, copper sintering paste or similar.

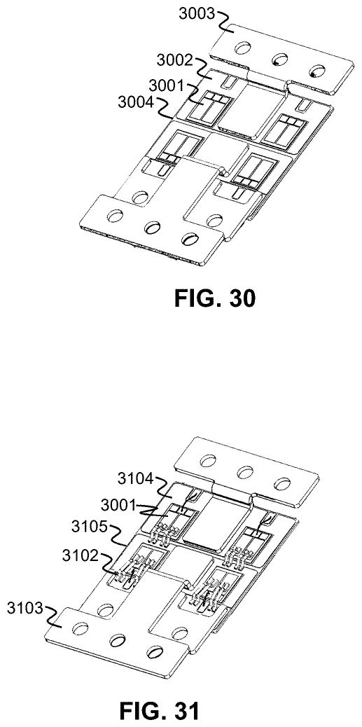

FIG. 30 shows the attachment of a semiconductor device 3001 to the layout layer. In general, the semiconductor device 3001 may be a semiconductor power device or semiconductor processing device, e.g., in the form of a chip. Semiconductor power devices include IGBTs, power MOSFETs, silicon controlled rectifiers (SCR), triacs, thyristors, and diodes, among others. Semiconductor processing devices include analog and digital integrated circuit (IC) devices, such as microprocessors, microcontrollers, semiconductor memory devices, digital signal processors, analog signal processing devices system-on-a-chip (SoC) devices, and more. Semiconductor devices may be made from any semiconductor material for example and without limitation, silicon, silicon carbide, gallium nitride, gallium arsenide, germanium, indium phosphide, indium antimonide, strontium titanate or diamond.

Semiconductor devices 3001 are placed over the sintering paste on the layout layer 3002. The semiconductor device 3001, and Layout layer 3002, Bus bars, 3003 SCD wafer 3004 assembly is exposed to sufficient heat and pressure to bond the semiconductor device 3001 to the layout layer 3002. For example, and without limitation the assembly may have around 16 mega Pascals of pressure applied to it while heated, e.g., with sinter-press plates at 230 degrees Celsius for 6 minutes or less.

FIG. 31 depicts the formation of bond wires from the semiconductor device 3001 to the etched layout layer 3104. The bond wires 3102 may be formed by any known method such as, for example and without limitation ball bonding, wedge bonding or compliant bonding. The bond wires may be a suitable thickness and conductivity to form a conductive connection between conductive terminal pads on the semiconductor device 3001 and the layout layer 3104. The size and location of the bond wires may be chosen to create a sufficient connection for high powered operation of the semiconductor device 3001. Additionally, the busbars 3103 may be conductively coupled to the layout layer through the sintered connection. The busbars 3103 may be used as part of the semiconductor device package to provide input current to or output current from the semiconductor device package through the layout layer.

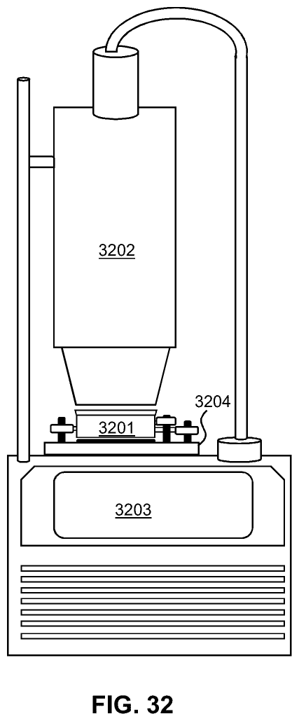

FIG. 32 shows the SCD integrated device package being tested in a thermographic testing system according to aspects of the present disclosure. The thermographic testing system may include a test head 3202, thermographic test control unit 3203 and the test jig 3204. The test jig 3204 may include sufficient conductive connection points to connect to and operate the SCD device package under a high-powered load. The test head may include a thermal imaging camera, such as an infrared imaging camera. By way example and without limitation, the test jig may include conductive pegs which are configured to connect with the bus bars of the SCD device package. The SCD device package 3201 is placed in the test jig 3204. The conductive pegs may, for example and without limitation fit into screw holes in the bus bars of the SCD device package.

The thermographic test system may pass a high voltage and current through the test jig 3204 to the SCD device package 3201 placing the SCD device package 3201 under a high-powered load. During the test, the head may detect the thermal output of the SCD device package when it is under the high-powered load and send the detected thermal output information to the thermographic test control unit 3203. The thermographic test control unit may interpret the thermal output information and control the test head and test jig. For example, and without limitation, the thermographic test control unit may control the voltage and current output by the test jig and may also control the magnification, shutter speed, sample rate, test head distance, calibration and aperture size of the test head. The thermographic test control unit may also include an interface that outputs information to a user and allow the user to control the test. The interface may include a Liquid Crystal display screen, Cathode ray tube display, Plasma display or similar. Additionally, the interface may include controls such as nobs, dials, keyboards, touch screen capability or similar to interact with the device.

Under high powered load during the thermographic test the silicon device package exhibits certain thermal characteristics. The silicon device package may have plus or minus 10 degree of thermal variation and maintain operation during the high-power load for the test period. The high-powered load may be for example and without limitation greater than 100 kilowatts. The test period depends on how long it takes to heat up the device. During proper operation the silicon device package shunts heat through the layout layer to the SCD wafer. The uniformity of the SCD wafer ensures that thermal energy is efficiently conducted from the device. During the test the SCD wafer may show no more than plus or minus 10 degree of temperature variation across at least 60, 70, 80, or 90 percent its surface. Depending on conditions, the SCD wafer may show as little as plus or minus 5 degree of temperature variation across at least 60, 70, 80 or 90 percent or more of its surface. The SCD wafer has a thermal conductivity in both the lateral and transverse directions of equal to or greater than 1900 Watts per meter. Kelvin (W/mK). The thermal conductivity of the SCD wafer may be up to 3000 W/mK.

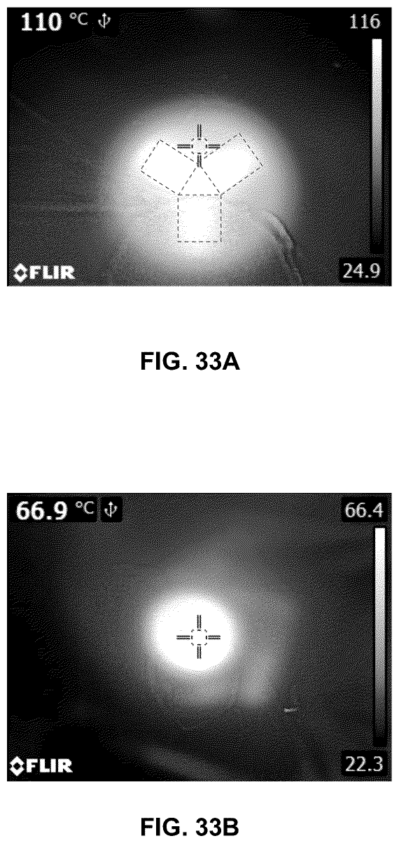

The thermographic images depicted in FIG. 33A and FIG. 33B illustrate the advantages of an SCD insulator wafer in an inverter device operating at high power. Each thermographic image shows the backside of an insulator of an inverter device having three MOSFETs attached to the front side of a silver-plated copper layout layer. In both images, the backside of the layout layer is attached to the front side of the insulator layer. The arrangement of the MOSFETs on the layout layer is the same in each image. The MOSFETs operate at 1200 volts and 100 amperes for seven seconds with no external cooling. In FIG. 33A, the inverter device uses an Aluminum Nitride (AlN) insulator wafer. The thermographic image in FIG. 33A clearly shows hot spots corresponding to the locations of the three MOSFETs. The hotspots outlined by the dashed lines in FIG. 33A are 30 to 40 centigrade degrees warmer than surrounding portions of the layout layer not covered by the MOSFETs. In FIG. 33B, by contrast, the inverter device uses a SCD insulator wafer. The thermographic image in FIG. 33B shows a temperature variation across at least 60%, 70%, 80% or 90% of the surface of the wafer of no more than plus or minus 10 centigrade degrees and as little as plus or minus 5 centigrade degrees with no discernible hot spots. Furthermore, the overall temperature of the device in FIG. 33B is about 44 centigrade degrees cooler than that in FIG. 33A.

Recent work by the inventor has shown that great improvements in operating efficiency of semiconductor processing devices are possible if an SCD wafer is suitably configured and integrated with a semiconductor processing device into a device package. In particular, in conventional semiconductor processing device packages without an SCD wafer have been observed to exhibit highly non-uniform temperature distribution characterized by hot spots of the type shown in FIG. 33A and 70% to 80% loss of processing power when operated at high power. By contrast, semiconductor processing device packages with an SCD wafer integrated into the device package as described herein have been observed to exhibit uniform temperature distribution of the type shown in FIG. 33B and no discernible loss of processing power when operated under the same high power conditions.

For the reasons discussed above, semiconductor devices packages, including power semiconductor device packages and semiconductor processing device packages in accordance with aspects of the present disclosure can operate efficiently due to improved thermal management.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature described herein, whether preferred or not, may be combined with any other feature described herein, whether preferred or not. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A integrated device component having improved thermal characteristics comprising:
a semiconductor device;
a layout layer disposed on the semiconductor device; and
a wafer located on top of the layout layer wherein the wafer is composed of a material chosen to be electrically resistive and have a thermal conductivity in a lateral and transverse direction of greater than or equal to 1900 watts per Meter Kelvin with a temperature variation over at least 60 percent of the surface of the wafer of no more than plus or minus 10 degree Celsius when the semiconductor device is subject to a high power load.

2. The integrated device component of claim 1 wherein the wafer is greater than 1 millimeter in the transverse axis.

3. The integrated device component of claim 2 wherein the wafer is greater than 4 mm in the transverse axis.

4. The integrated device component of claim 3 wherein the wafer is greater than 10 mm in the transverse axis.

5. The integrated device component of claim 4 wherein the wafer is greater than 100 mm in the transverse axis.

6. The integrated device component of claim 2 wherein the wafer is circular and the traverse axis is a diameter of the circular wafer.

7. The integrated device component of claim 1 wherein the semiconductor device and wafer are affixed to the layout layer in such a way that the temperature variation when the device is subject to the high power load is no more than plus or minus 5 Centigrade degrees of temperature variation of over at least 60 percent of the surface of the wafer.

8. The integrated device component of claim 1 wherein the high power load is greater than 100 kilowatts.

9. The integrated device component of claim 1 wherein the wafer is chosen to have a dielectric strength of 10 MV/CM.

10. The integrated device component of claim 1 wherein the wafer is between 50 micrometers and 1000 micrometers thick in the lateral axis.

11. The integrated device component of claim 1 wherein the layout layer includes at least one material from the group consisting of copper. gold, silver and aluminum.

12. The integrated device component of claim 1 wherein the layout layer wherein the layout layer is between 30 micrometers and 300 micrometers thick in the lateral axis.

13. The integrated device component of claim 1 further comprising a first sintered layer between the silicon device package and the layout layer.

14. The integrated device component of claim 13 wherein the sintered layer includes silver.

15. The integrated device component of claim 13 wherein the layout layer is formed on a surface of the wafer.

16. The integrated device component of claim 1 further comprising a sintered layer between the wafer and the layout layer.

17. The integrated device component of claim 16 wherein the sintered layer includes silver.

18. The integrated device component of claim 1. wherein the semiconductor device is a semiconductor processing device.

19. The integrated device component of claim 1. wherein the wafer has a thermal conductivity in a lateral and transverse direction of greater than or equal to 1900 watts per Meter Kelvin.
